(19) United States
(12) Patent Application Publication
(10) Pub. No.: US 2025/0316962 A1
(43) Pub. Date: Oct. 9, 2025

(54) PHOTONIC DEVICES WITH IMPROVED LATERAL CURRENT CONFINEMENT

(71) Applicant: SIVERS PHOTONICS LIMITED, Blantyre, Glasgow (GB)

(72) Inventor: Andrew MCKEE, Glasgow (GB)

(73) Assignee: SIVERS PHOTONICS LIMITED, Blantyre, Glasgow (GB)

(21) Appl. No.: 18/867,389

(22) PCT Filed: May 19, 2023
(86) PCT No.: PCT/GB2023/051333

§ 371 Date: Nov. 19, 2024

(30) Foreign Application Priority Data
May 20, 2022 (GB) 2207452.0

(51) Int. Cl. H01S 5/20; H01S 5/22

(52) U.S. Cl. CPC H01S 5/2054; H01S 5/22

(57) ABSTRACT

A photonic device has a lower epitaxial layer structure that includes an active layer structure and a channel defined by a current blocking region patterned by selective introduction of material (by implantation or diffusion) into the lower epitaxial layer structure. The lower epitaxial layer structure may include a grating layer and the photonic device may further include a distributed feedback grating patterned into the grating layer. An upper epitaxial layer structure is overgrown on the lower epitaxial layer structure including the introduced material. A ridge waveguide may be etched into the upper epitaxial layer structure and superimposed on the channel.

The present invention relates to photonic devices, chips and photonic chip assemblies, in particular photonic devices using lateral current confinement.

### BACKGROUND ART

In the field of semiconductor lasers, lateral current confinement is used to lower threshold current and increase efficiency.

In the field of ridge-waveguide semiconductor lasers, lateral confinement technology gives the ability to reduce the current injection width compared to the horizontal waveguide width. This allows higher power laser designs due to wider ridges and larger optical modes.

Chen et al, Ridge semiconductor laser with laterally undercut etched current confinement structure, IEEE Trans Electron., Vol E.90-C, No 5, May 2007 discloses lateral current confinement using a selective undercut etching method and references others' reversed mesa and laterally oxidised ridged lasers, which also provide lateral current confinement.

There are various problems with such approaches.

The use of selective etch and lateral oxidation impose constraints on the materials used, needing non-standard layers to be etched or oxidised.

For ridge waveguide devices, the width of the gap between etched or oxidised regions that provide lateral current confinement is dependent on the ridge width. This is because the etch and oxidation start at the waveguide edges, progressing towards the centre of the waveguide over time.

Furthermore, wet etching when used to make isolating regions for lateral current confinement has relatively large process variation.

U.S. Pat. No. 5,193,098 in the name of Spectra Diode Laboratories, Inc discloses a method of forming current barriers in semiconductor lasers using implanted ions to form a buried barrier for current confinement. In one embodiment, an implant is made through the top of a substrate prior to growth of lower cladding, active, upper cladding and cap layers. A problem with that approach is that lateral confinement is affected by current spreading and carrier diffusion as the isolating regions are relatively far from the active layers.

U.S. Pat. No. 5,193,098 also discloses deep implants through all the epilayers into the active layer to make isolating regions for lateral current confinement. However, that approach will cause implant damage in the active layers and will also have relatively large lateral variation.

### SUMMARY OF INVENTION

It is desirable to provide photonic devices, including ridge waveguide photonic devices, chips and photonic chip assemblies, that overcome at least some of the above-identified problems. It is desirable to provide lateral current confinement in a photonic device where current spreading is reduced and where there is low damage and less lateral process variation. In particular, it is desirable to provide lateral current confinement in a ridge waveguide photonic device that is independent of the ridge width, without use of special etches or layers, where current spreading is reduced and where there is low damage and less lateral process variation.

According to a first aspect of the present invention, there is provided a photonic device comprising:
a lower epitaxial layer structure comprising:
   an active layer structure; and
   a channel, defined by a current blocking region patterned by selective introduction of material into the lower epitaxial layer structure; and
   an upper epitaxial layer structure overgrown on the lower epitaxial layer structure comprising the introduced material.

Preferably, the current blocking region is patterned by selective introduction of material from above the active layer into the lower epitaxial layer structure and the upper epitaxial layer structure is overgrown above the active layer on the lower epitaxial layer structure.

Preferably, the lower epitaxial layer structure comprises a grating layer and the photonic device further comprises a distributed feedback grating patterned into the grating layer.

Preferably, the upper epitaxial layer structure comprises a cladding layer under a contact layer.

Preferably, the photonic device further comprises a ridge waveguide etched into the upper epitaxial layer structure and superimposed on the channel.

Preferably, the ratio of width of the channel to width of the ridge waveguide varies along the length of the channel.

Preferably, the channel has a constant width along the length of the channel.

Alternatively, the ridge waveguide has a constant width along the length of the channel.

Preferably, the ridge waveguide is wider than the channel, along the whole length of the channel.

Preferably, the current blocking region is patterned by ion implantation into the lower epitaxial layer structure.

Preferably, the current blocking region is patterned by selective area isolation implantation into the lower epitaxial layer structure.

Alternatively, the current blocking region is patterned by selective area doping implantation into the lower epitaxial layer structure.

Alternatively, the current blocking region is patterned by selective area doping diffusion into the lower epitaxial layer structure.

Preferably, the lower epitaxial layer further comprises a current blocking layer having a first conductivity type and a species of the doping is selected to form the channel in the current blocking layer, with the channel having an opposite conductivity type to the first conductivity type.

Preferably, the photonic device is a laser.

According to a second aspect of the present invention, there is provided a photonic chip comprising the photonic device of the first aspect.

According to a third aspect of the present invention, there is provided a photonic chip assembly comprising the photonic chip of the second aspect and a photonic integrated circuit having a receiving waveguide aligned to receive a beam of radiation from the photonic chip, the beam having propagated along the channel.

According to a fourth aspect of the present invention, there is provided a photonic chip assembly comprising the photonic chip of the second aspect and a photonic integrated circuit having a launching waveguide aligned to launch a beam of radiation to the photonic chip, the beam of radiation entering the channel to propagate along the channel.

According to a fifth aspect of the present invention, there is provided a method of fabrication of a photonic device, the method comprising the steps:
growing a lower epitaxial layer structure comprising an active layer structure;
patterning a current blocking region, by selective introduction of material into the lower epitaxial layer structure, to define a channel; and
overgrowing an upper epitaxial layer structure on the lower epitaxial layer structure comprising the introduced material.

Preferably, the patterning of the current blocking region, is by selective introduction of material from above the active layer into the lower epitaxial layer structure and the upper epitaxial layer structure is overgrown above the active layer on the lower epitaxial layer structure.

Preferably, the method further comprises the step of etching a ridge waveguide into the upper epitaxial layer structure, superimposed on the channel.

Preferably, the method further comprises the step of patterning the ridge waveguide such that the ridge waveguide is wider than the channel, along the whole length of the channel.

Preferably, the lower epitaxial layer structure comprises a grating layer and the method further comprises the step of patterning a distributed feedback grating on the grating layer prior to the step of overgrowing the upper epitaxial layer structure.

Preferably, the upper epitaxial layer structure comprises a cladding layer under a contact layer.

Preferably, the step of patterning the current blocking region by selective introduction of material into the lower epitaxial layer structure comprises ion implantation into the lower epitaxial layer structure.

Preferably, the step of patterning the current blocking region by selective introduction of material into the lower epitaxial layer structure comprises selective area isolation implantation into the lower epitaxial layer structure.

Alternatively, the step of patterning the current blocking region by selective introduction of material into the lower epitaxial layer structure comprises selective area doping implantation into the lower epitaxial layer structure.

Alternatively, the step of patterning the current blocking region by selective introduction of material into the lower epitaxial layer structure comprises selective area doping diffusion into the lower epitaxial layer structure.

Preferably, the lower epitaxial layer further comprises a current blocking layer having a first conductivity type and a species of the doping is selected to form the channel in the current blocking layer, with the channel having an opposite conductivity type to the first conductivity type.

According to a sixth aspect of the present invention, there is provided a ridge waveguide photonic device comprising:
a lower epitaxial layer structure comprising:
   an active layer structure; and
   a channel defined by a current blocking implant, into the lower epitaxial layer structure;
an upper epitaxial layer structure overgrown on the lower epitaxial layer structure; and
a ridge waveguide etched into the upper epitaxial layer structure and superimposed on the channel.

Preferably, the lower epitaxial layer structure comprises a grating layer and the ridge waveguide photonic device further comprises a distributed feedback grating patterned into the grating layer. Preferably, the upper epitaxial layer structure comprises a cladding layer under a contact layer.

Preferably, the ratio of width of the channel to width of the ridge varies along the length of the channel. Preferably, the channel has a constant width along the length of the channel. Alternatively, the ridge waveguide has a constant width along the length of the channel. Preferably, the ridge waveguide is wider than the channel, along the whole length of the channel.

Preferably, the waveguide photonic device is a laser.

According to a seventh aspect of the present invention, there is provided a photonic chip comprising the ridge waveguide photonic device of the sixth aspect.

According to an eighth aspect of the present invention, there is provided a photonic chip assembly comprising the photonic chip of the seventh aspect and a photonic integrated circuit having a receiving waveguide aligned to receive a beam of radiation from the photonic chip, the beam having propagated along the waveguide.

According to a ninth aspect of the present invention, there is provided a photonic chip assembly comprising the photonic chip of the seventh aspect and a photonic integrated circuit having a launching waveguide aligned to launch a beam of radiation to the photonic chip, the beam of radiation entering the waveguide to propagate along the waveguide.

According to a tenth aspect of the present invention, there is provided a method of fabrication of a ridge waveguide photonic device, the method comprising the steps:
growing a lower epitaxial layer structure comprising an active layer structure;
implanting a current blocking implant, into the lower epitaxial layer structure to define a channel;
overgrowing an upper epitaxial layer structure on the lower epitaxial layer structure; and
etching a ridge waveguide into the upper epitaxial layer structure superimposed on the channel.

Preferably, the method further comprises the step of patterning the ridge waveguide before etching it such that ridge waveguide is wider than the channel, along the whole length of the channel.

Preferably, the lower epitaxial layer structure comprises a grating layer and the method further comprises the step of patterning a distributed feedback grating on the grating layer prior to the step of overgrowing the upper epitaxial layer structure. Preferably, the upper epitaxial layer structure comprises a cladding layer under a contact layer.

### BRIEF DESCRIPTION OF DRAWINGS

Embodiments of the present invention will now be described, by way of example only, with reference to the drawings, in which:

FIGS. 1a to 1c illustrate, in schematic form, a known etched-facet distributed feedback (DFB) laser chip, in orthographic and cross-section views.

FIGS. 2a to 2c illustrate, in schematic form, an etched-facet DFB laser chip in accordance with an embodiment of the present invention, in orthographic and cross-section views.

FIG. 3 illustrates, in schematic form, a method of fabrication of a ridge waveguide photonic device in accordance with an embodiment of the present invention, with cross-section views.

FIG. 4 illustrates, in schematic form, a flared ridge waveguide and current blocking implants in accordance with an embodiment of the present invention, in a plan view.

FIG. 5 illustrates, in schematic form, a ridge waveguide with a flared channel between current blocking implants in accordance with an embodiment of the present invention, in a plan view.

FIG. 6 illustrates, in schematic form, a method of fabrication of a photonic device in accordance with another embodiment of the present invention, with cross-section views.

FIG. 7 illustrates, in schematic form, steps from a method of fabrication of a photonic device in accordance with another embodiment of the present invention, with cross-section views.

### DETAILED DESCRIPTION

In this description and claims, optical and optical radiation relate to electromagnetic radiation over a range of wavelengths not limited to visible radiation, such as wavelengths spanning ultraviolet, visible and infrared radiation. An InP distributed feedback (DFB) laser is described as an example of a photonic device. Other compound semiconductor based devices may be used with embodiments. For example photonic devices based on GaAs, GaSb, or GaN, or photonic devices based on other material systems, may be used. Rather than the DFB laser example described herein, other photonic devices may be used, such as Fabry Perot lasers, semiconductor optical amplifiers (SOAs), reflective semiconductor optical amplifiers (RSOAs) used stand-alone or in external cavity lasers.

The examples described herein relate to photonic devices fabricated with an etched facet, but the skilled person will appreciate that embodiments may include photonic devices fabricated with a cleaved facet.

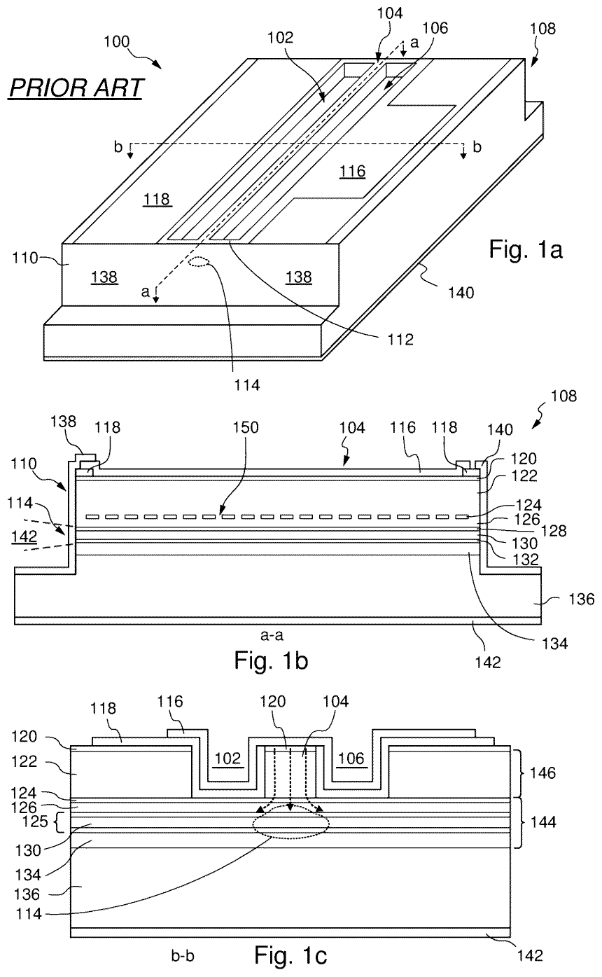

FIG. 1 illustrates a known photonic device, in this example an etched-facet laser chip 100, with a compound semiconductor laser on an InP (indium phosphide) substrate. FIG. 1a is an orthographic view of the laser chip 100. FIG. 1b is a cross-section (not to scale) along a-a shown in FIG. 1a. FIG. 1b is thus a cross-section through the waveguide 104 along its propagation direction (length). FIG. 1c is a cross-section (not to scale) along b-b shown in FIG. 1a. FIG. 1c is thus a cross-section across the waveguide 104 perpendicular to its propagation direction.

The structure of the laser chip 100 is now described in the context of its wafer-scale fabrication.

A ridge waveguide 104 is defined by a waveguide etch. A pattern of openings in a hard mask in a lithographic step defines trenches 102, 106 that are etched to define the ridge waveguide 104 in between them. An insulating dielectric material 118 covers most of the top surface, and a contact window is opened up in the dielectric along the top of the ridge 104. Subsequently, metal 116 is deposited covering the ridge waveguide and making contact through the contact window to the top of the ridge waveguide 104.

A pad of the metal 116 at one side of the ridge waveguide is used as an area for soldering or bonding to the metal. In subsequent fabrication steps, a patterned hard mask and facet etch defines front and rear etched facets 110, 108 at either end of the ridge waveguide 104. The facet etch creates an etched surface which extends either side of the etched facet. The facet etch is deeper than the ridge etch.

A small horizontal spacing is provided between the ridge trenches 102, 106 and the facet etch features, so that the front and rear etched facets 110, 108 are etched as flat planes rather than having corners with the ridge waveguide, which would etch unevenly and would be detrimental to the smoothness of the facet at the end of the waveguide. This results in a structure shaped like a T, with the waveguide being the trunk of the T, and walls 112 being the crossbar of the T. The effect of the spacing and resulting T-shaped structure is to ensure that the facet is smooth to provide efficient and reproducible transmission through optical coupling regions, or internal reflection at, the facets.

After the facet etch, an anti-reflective (AR) coating 138 is applied to one etched facet 110 and a high-reflectance (HR) coating 140 (or an AR coating, not shown) is applied to the other etched facet 108 at the other end of the waveguide 104. Anti-reflective coatings may be applied to just one facet for a laser, or one or both facets for Semiconductor Optical Amplifiers (SOAs) or Electro-Absorption Modulators (EAMs).

Finally, a metallisation step coats the underside of the wafer with metal 142.

With reference to FIGS. 1a and 1b, in operation the laser cavity, comprising the waveguide 104 bounded by facets 108 and 110 at either end, outputs optical radiation 142 through an optical coupling region 114.

With reference to FIGS. 1b and 1c, the layer structure will now be described in detail. From the top in FIG. 1b, a p-metal layer 116 extends down through a window in the dielectric layer 118. The p-metal layer 116 makes contact to a p-type InGaAs contact layer 120, which is the top epitaxially-grown layer. Below that, a p-type InP cladding layer 122 is followed by a p-type etch stop/grating layer 124. The etch that stops on that layer 124 is the waveguide ridge etch, as illustrated in FIG. 1c. Next, a p-type InP spacer layer 126 is followed by a p-type separate confinement heterostructure (SCH) layer 128, an undoped multi-quantum well (MQW) layer 130, and an n-type SCH layer 132. The SCH and MQW layers are the optically active layers in the laser.

The n-type InP buffer layer 134 is the first of the epitaxial layers that is grown on the n-type InP substrate 136.

In a distributed feedback (DFB) laser, a grating is superimposed on the waveguide to provide optical feedback in the laser cavity. In this example, the grating is made by performing the epilayer growth in two stages and in between the stages patterning the grating. First, a lower epitaxial layer structure 144 is grown on the substrate, starting with the n-type InP buffer layer 134 then the SCH and MQW active layers 125 then the p-type InP spacer layer 126 and the etch stop/grating layer structure 124. Electron beam lithography is used to define a grating pattern 150 (shown in FIG. 1b), which is transferred by etching into the etch stop/grating layer structure 124.

After the grating patterning, the upper epitaxial layer structure 146 is overgrown on the lower epitaxial layer structure 144, using for example metalorganic vapour-phase epitaxy (MOCVD). The upper epitaxial layer structure 146 includes the p-type InP cladding layer 122 under the p-type InGaAs contact layer 120.

This specific layer structure is suitable for a laser as well as an SOA. However, the layer structure may be optimised for different active photonic devices.

In this laser example, the front and rear etched facets 110, 108 are coated with a PECVD-deposited silicon nitride AR coating 138 and an HR coating 140 respectively. The AR coating is selectively removed after deposition to allow bonding to metallic layers.

Finally, the n-metal layer 142 is shown.

In operation, as shown at the left of FIG. 1b, a beam of optical radiation 140, illustrated bounded with dashed lines, is output from the etched facet 110 at the optical coupling region 114. In this example, the optical radiation is output from the optically active layers of the ridge waveguide 128, 130, 132 (collectively labelled 125 in FIG. 1c) into the air to the left of the front etched facet 110. For an SOA example (not shown), instead of an HR coating 140 another AR coating is applied to the rear etched facet 108 and radiation is input to the waveguide at the rear etched facet 108.

With reference to FIG. 1c, the p-metal layer 116 can be seen on top of the dielectric layer 118 as it covers trenches 102, 106 either side of the ridge waveguide 104. The p-metal layer 116 contacts the top of the ridge 104 through a window in the dielectric 118. The trenches 102, 106 are etched by the waveguide etch, which selectively stops on the p-type etch stop/grating layer 124.

The location of the optical coupling region 114 is shown projected along the waveguide from the etched facet 110 onto this cross-section plane b-b. It is centred horizontally with respect to the ridge waveguide 104 and centred vertically with respect to the undoped MQW layer 130.

With reference to FIG. 1c, dotted arrows show the current flow in the ridge. A contact is made by the metal layer 116 at the top of ridge 104 to the p-type InGaAs contact layer 120. Current spreads outwards from under the ridge 104 towards the active layer 125 because it is not laterally confined when it leaves the ridge downwards towards the active layers. Therefore the whole of the optical mode is supplied with current. The optical mode roughly corresponds to the projected coupling region 114.

In the drawings of FIG. 1 and in subsequent drawings, features labelled with the same numerals correspond to the same features in subsequent drawings. Therefore a description of a feature in any drawing should also apply to a feature labelled with the same numeral elsewhere in this description.

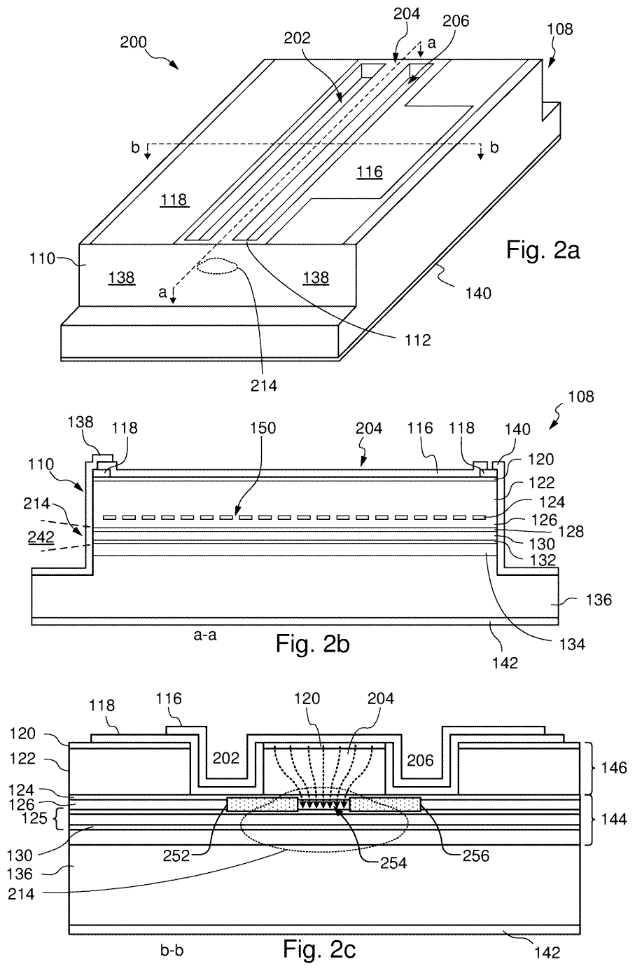

FIGS. 2a to 2c illustrate, in schematic form, an etched-facet DFB laser chip in accordance with an embodiment of the present invention, in orthographic and cross-section views.

With reference to FIG. 2a, the photonic device 200 is different from the device illustrated in FIG. 1a. The ridge waveguide 204 is defined by a waveguide etch but is wider. Trenches 202, 206 are etched to define the wider ridge waveguide 204 in between them.

The skilled person will appreciate that embodiments are not limited to photonic device structure to an n-i-p structure starting from the substrate, but may also be implemented in an inverted p-i-n structure (not shown).

With reference to FIGS. 2a and 2c, in operation the laser cavity, comprising the ridge waveguide 204 bounded by facets 110 and 108 at either end, outputs optical radiation 242 through an optical coupling region 214. Because the ridge 204 is wider, the optical coupling region 214 in FIG. 2a is wider than the optical coupling region 114 that results from the narrower ridge 104 in FIG. 1a.

As shown in FIG. 2c, the photonic device 200 has a lower epitaxial layer structure 144 that includes the active layer structure 125 and a channel 254 defined by a current blocking region patterned by selective introduction of material into the lower epitaxial layer structure 144. In this example, the current blocking region is a current blocking implant 252, 256, which is patterned by ion implantation into the lower epitaxial layer structure 144. The patterning may be achieved using for example a patterned resist or hard implant mask, or direct-write ion implantation.

The current blocking implant may be patterned by selective area isolation implantation into the lower epitaxial layer structure. Alternatively, the current blocking region may be patterned by selective area doping implantation into the lower epitaxial layer structure.

In another example, the current blocking region may be patterned by selective area doping diffusion into the lower epitaxial layer structure, using for example a patterned hard mask to block diffusion in selected areas.

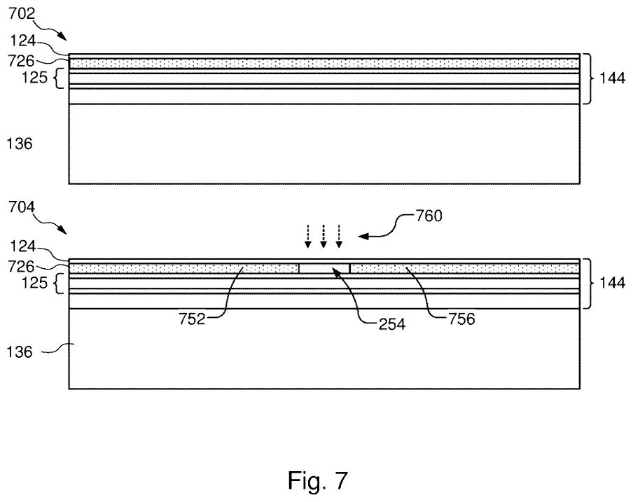

In another example (described below with reference to FIG. 7), the lower epitaxial layer further comprises a current blocking layer 752 having a first conductivity type. The species of the doping implantation or diffusion is selected to form the channel in the current blocking layer, with the channel having an opposite conductivity type to the first conductivity type.

The ridge waveguide 204 is wider than the channel 254, along the whole length of the channel.

As mentioned above, a current blocking implant may define the channel by being an isolated region. The implant in this case may be referred to as an isolation implant. In this current blocking mechanism, the implanted ions create a highly resistive region that blocks the lateral flow of current. The implanted ions can create lattice damage, introduce impurities or point defects, or modify the bandgap of the lower epitaxial structure, all of which can contribute to increasing the resistance of the implanted regions 252, 256.

The doping implant or diffusion may define the channel by forming a PN junction barrier. The implant or diffusion in this case may be referred to as a selective area doping (SAD) implant or diffusion. In this current blocking mechanism, the introduced species create regions 252, 256 of different conductivity type (e.g. n-type) from the adjacent non-implanted or non-diffused region 254 in the same layer (e.g. p-type layers 125, 126) to define the channel 254.

An upper epitaxial layer structure 146 is overgrown on the lower epitaxial layer structure 144 comprising the introduced material. In this example the upper epitaxial layer 146 is overgrown on the already-implanted lower epitaxial layer structure 144. The ridge waveguide 204 is etched into the upper epitaxial layer structure 146 and superimposed on the channel 254.

For isolation implant, or doping by implantation or diffusion, the current blocking region 252, 256 is patterned by selective introduction of material from above the active layer 125 into the lower epitaxial layer structure 144, and the upper epitaxial layer structure 146 is overgrown above the active layer 125 on the lower epitaxial layer structure 144.

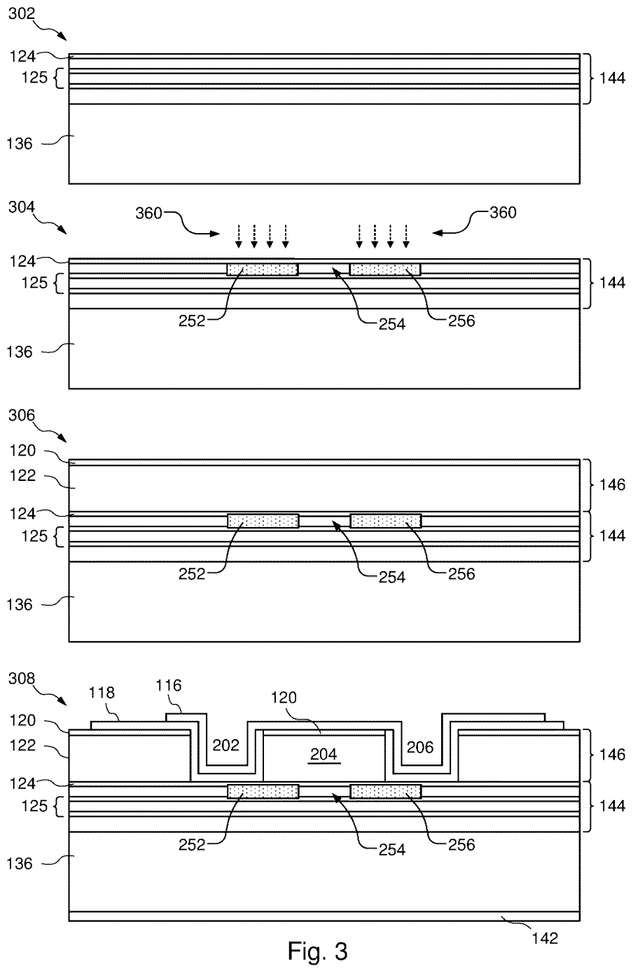

Like for the device in FIG. 1, the photonic device 200 is a distributed feedback (DFB) laser, and a grating is superimposed on the waveguide to provide optical feedback in the laser cavity. The implantation or diffusion of the current blocking region 252, 256 is performed at the same stage of processing as the patterning of the grating, i.e. in between the epitaxial growth of the lower epitaxial layer structure 144 and the upper epitaxial layer structure 146. Thus, in this example, the implantation or diffusion is made in to the surface of the etch stop/grating layer 124, as will be described with reference to FIG. 3.

With reference to FIG. 2c, dotted arrows show the current flow in the ridge. A large area low-resistance contact is made by the metal layer 116 at the top of ridge 204 to the contact semiconductor layer 120. The current flow is laterally confined to the channel 254 by the blocking regions 252, 254. Current cannot leak at the side of the ridge 204 from the upper contact layer 120 on the ridge to the substrate 136 because the shallow implants or diffusions extend laterally outwards from the channel beyond the edge of the ridge while being close to the etch stop layer down to which the trenches defining the ridge are etched. Therefore just the centre of the optical mode is supplied with current. The optical mode roughly corresponds to the projected optical coupling region 214.

Unlike selectively undercut etched or laterally oxidised lateral confinement structures, the lateral current confinement is independent of the waveguide width. This is because the waveguide width and channel width are defined by separate lithographic steps.

Because the implant is after epi (active layer) growth and before epi (upper cladding layer) overgrowth, a low-energy shallow implant (through the p-doped layers close to the channel) can be placed close, but not into, to the active layers thus minimizing implant damage in the active layers.

Because the shallow implant is close to the active layers, less current spreading can be achieved, but without causing damage in the active layers. Preferably, the channel is defined by a current blocking implant or diffusion, introduced into the lower epitaxial structure close to active layer structure. An implant or diffusion has a depth distribution, so an implant or diffusion close to the active layer structure may have its distribution mainly above the active layer structure but have a small part of its distribution extending down into the active layer structure. Preferably, the peak as-implanted (i.e. before annealing or other thermal processing) or as-diffused concentration of the introduced material species as a function of depth is above the active layer structure. The as-implanted or as-diffused concentration of the implant species at the upper interface of the active layer is preferably less than 1×10¹⁸ atoms/cm³, more preferably less than 1×10¹⁷ atoms/cm³, most preferably less than 1×10¹⁶ atoms/cm³.

As described with reference to FIG. 1, an insulating dielectric material 118 covers most of the top surface, and a contact window is opened up in the dielectric along the top of the ridge 204. Subsequently, metal 116 is deposited covering the ridge waveguide and making contact through the contact window to the top of the ridge waveguide 204.

A pad of the metal 116 at one side of the ridge waveguide is used as an area for soldering or bonding to the metal. In subsequent fabrication steps, a patterned hard mask and facet etch defines front and rear etched facets 110, 108 at either end of the ridge waveguide 204. The facet etch creates an etched surface which extends either side of the etched facet. The facet etch is deeper than the ridge etch.

After the facet etch, an anti-reflective (AR) coating 138 is applied to one etched facet 110 and a high-reflectance (HR) coating 140 (or an AR coating, not shown) is applied to the other etched facet 108 at the other end of the waveguide 204. Anti-reflective coatings may be applied to just one facet for a laser, or one or both facets for Semiconductor Optical Amplifiers (SOAs) or Electro-Absorption Modulators (EAMs).

Finally, a metallisation step coats the underside of the wafer with metal 142.

FIG. 3 illustrates, in schematic form, a method of fabrication of a ridge waveguide photonic device in accordance with an embodiment of the present invention, with cross-section views along b-b in FIG. 2a, like FIG. 2c.

The method has the steps:

302: growing a lower epitaxial layer structure 144 comprising an active layer structure 125. When a DFB laser is being fabricated, the lower epitaxial layer structure 146 may further comprise a grating layer 124.

304: patterning a current blocking region 252, 256 by selective introduction of material 360 into the lower epitaxial layer structure 144 to define a channel 254.

Patterning the current blocking region 252, 256 by selective introduction of material 360 into the lower epitaxial layer structure 144 may comprise ion implantation into the lower epitaxial layer structure. This implantation may be selective area isolation implantation and/or selective area doping implantation into the lower epitaxial layer structure, using for example a patterned implant mask, or direct-write ion implantation.

Patterning the current blocking region 252, 256 by selective introduction of material 360 into the lower epitaxial layer structure 144 may comprise selective area doping diffusion into the lower epitaxial layer structure, using for example a patterned hard mask to block diffusion in selected areas.

Suitable current blocking isolation implant ion species are H, He, N and Fe. Implant energies may for example be in the range 200 keV to 500 keV with peak implant concentrations in the range 10¹⁷ to 10¹⁹/cm³. If an isolation implant is used to define the channel, then the thermal profile (time and/or temperature) of the subsequent epitaxial growth is limited, so as to avoid annealing out the damage and reversing the isolation so as to reduce lateral current confinement to an unacceptable level. However, some post-implant annealing may be needed to increase the resistivity of the isolating regions. This can be provided by a separate annealing step. Alternatively or in addition, the thermal profile of the subsequent epitaxial growth may increase the resistivity of the isolating regions.

Suitable n-type current blocking SAD implant ion or diffusion species are Si, Sn, S, Se and Te. If the photonic device structure is inverted with p-i-n starting from the substrate, rather than the n-i-p structure described in relation to the figures, suitable p-type current blocking SAD implant ion or diffusion species are Be, Mg, Zn and Cd. Implant energies may for example be in the range 200 keV to 500 keV with peak implant concentrations in the range 10¹⁷ to 10¹⁹/cm³. If a SAD implant is used to define the channel, then a separate annealing step may be used to activate the doping. Alternatively or in addition, the thermal profile of the subsequent epitaxial growth may activate the doping.

When a DFB laser is being fabricated, a distributed feedback grating 150 is patterned on the lower epitaxial layer structure 144 prior to the step of overgrowing the upper epitaxial layer structure 146.

306: overgrowing an upper epitaxial layer structure 146 on the lower epitaxial layer structure 144 comprising the introduced material. In this example the upper epitaxial layer structure 146 is grown by MOCVD.

Thus, the patterning of the current blocking region 252, 256 in step 304, is by selective introduction of material 360 from above the active layer 125 into the lower epitaxial layer structure 144 and the upper epitaxial layer structure 146 is overgrown above the active layer 125 on the lower epitaxial layer structure 144.

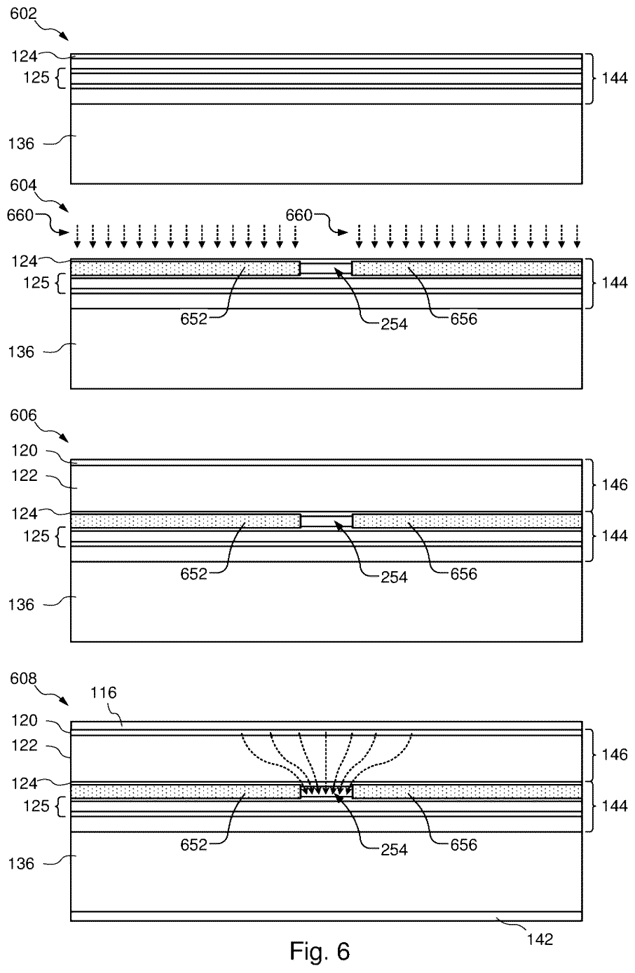

308: etching a ridge waveguide 204 into the upper epitaxial layer structure 146 superimposed on the channel 254. This step includes patterning the ridge waveguide such that the ridge waveguide is wider than the channel, along the whole length of the channel. In another embodiment, described with reference to FIG. 6, there is no etched ridge waveguide, so the step of etching a ridge is skipped.

The remaining fabrication steps through to metallisation of the underside of the wafer are described with reference to FIGS. 1 and 2c.

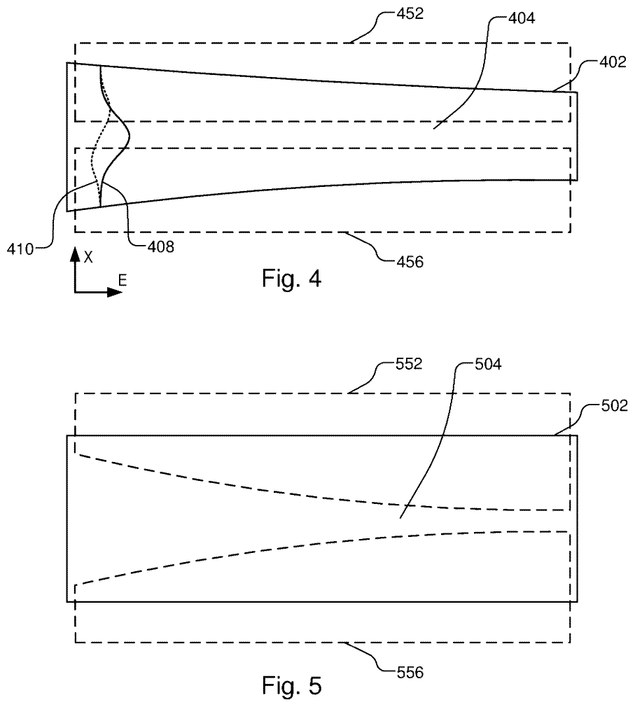

FIG. 4 illustrates, in schematic form, a flared ridge waveguide and current blocking regions in accordance with an embodiment of the present invention, in a plan view.

The current blocking regions are patterned by the selective introduction of material into the lower epitaxial layer structure 144, as described with reference to FIGS. 2 and 3. The ridge waveguide 402 is flared, in that its width varies along its length. It may be flared non-linearly as shown, or linearly, which is known as a taper. Rather than the ratio varying monotonically as shown, it may vary non-monotonically, such as having a narrowing or widening at the middle or both ends. The current blocking regions 452 and 456 (shown with a perimeter of dashed lines) have a gap 404 between them defining a channel that has a constant width along the length of the ridge waveguide. Thus the ratio of width of the channel to width of the ridge varies along the length of the channel. The ridge waveguide 402 is wider than the channel 404, along the whole length of the channel.

At the wider flared end of the ridge, the optical mode is wider and E fields are lower, so high output power is achieved with a lower peak power density at the facet. The electric field strength of the 0^{th} order transverse optical mode 408 is shown with the electric field axis going from left to right. The electric field strength of the 1^{st} order transverse optical mode 410 is shown with a dotted line. Lateral current confinement is useful because the current is supplied preferentially to the centre of the waveguide so it injects into the 0^{th} order transverse optical mode 408, more than into the less desirable 1^{st} order transverse optical mode 410.

FIG. 5 illustrates, in schematic form, a ridge waveguide with a flared channel between current blocking regions in accordance with an embodiment of the present invention, in a plan view. The current blocking regions 552 and 556 (shown with a perimeter of dashed lines) have a gap 504 between them defining a channel in the waveguide that is of constant width. The gap 504 is flared, in that its width varies along its length. It may be flared non-linearly as shown, or linearly, which is known as a taper, and vary monotonically or non-monotonically. Thus the ratio of width of the channel to width of the ridge varies along the length of the channel with the ridge waveguide 502 having a constant width along the length of the channel. The ridge waveguide 502 is wider than the channel 504, along the whole length of the channel.

FIG. 6 illustrates, in schematic form, a method of fabrication of photonic device in accordance with another embodiment of the present invention, with cross-section views across the channel. The method has the steps:

602: growing a lower epitaxial layer structure 144 comprising an active layer structure 125. When a DFB laser is being fabricated, the lower epitaxial layer structure 146 may further comprise a grating layer 124.

604: patterning a current blocking region 652, 656 by selective introduction of material 660 into the lower epitaxial layer structure 144 to define a channel 254.

Patterning the current blocking region by selective introduction of material 360 into the lower epitaxial layer structure may comprise ion implantation into the lower epitaxial layer structure. This implantation may be selective area isolation implantation and/or selective area doping implantation into the lower epitaxial layer structure, using for example a patterned implant mask, or direct-write ion implantation.

Patterning the current blocking region by selective introduction of material 360 into the lower epitaxial layer structure may comprise selective area doping diffusion into the lower epitaxial layer structure, using for example a patterned hard mask to block diffusion in selected areas.

The portions of the current blocking region 652, 656 are wider than the ones 252, 256 shown in FIGS. 2c and 3. In this example they extend to the edge of the chip. This is because in this embodiment there are no trenches (202 and 206 in FIG. 2c) in the upper cladding 122 either side of the channel 254, that would stop current leaking from the upper contact layer 120 down through the active layers to the substrate 136 around narrower current blocking regions. So, in this example, as well as defining the channel, the blocking region 652, 656 blocks current flow in parallel with the channel between the top contact layer 120 and the substrate 136. The examples described with reference to FIGS. 2c and 3, could also have a wider blocking region extending away from the channel, such as shown in FIG. 6, even extending to the edge of the chip.

Suitable current blocking isolation implant ion species are H, He, N and Fe. Implant energies may for example be in the range 200 keV to 500 keV with peak implant concentrations in the range 10¹⁷ to 10¹⁹/cm³. If an isolation implant is used to define the channel, then the thermal profile (time and/or temperature) of the subsequent epitaxial growth is limited so as to avoid annealing out the damage and reversing the isolation so as to reduce lateral current confinement to an unacceptable level. However, some post-implant annealing may be needed to increase the resistivity of the isolating regions. This can be provided by a separate annealing step. Alternatively or in addition, the thermal profile of the subsequent epitaxial growth may increase the resistivity of the isolating regions.

Suitable n-type current blocking SAD implant ion or diffusion species are Si, Sn, S, Se and Te. If the photonic device structure is inverted with p-i-n starting from the substrate, rather than the n-i-p structure described in relation to the figures, suitable p-type current blocking SAD implant ion or diffusion species are Be, Mg, Zn and Cd. Implant energies may for example be in the range 200 keV to 500 keV with peak implanted concentrations in the range 10¹⁷ to 10¹⁹/cm³. If a SAD implant is used to define the channel, then a separate annealing step may be used to activate the doping. Alternatively or in addition, the thermal profile of the subsequent epitaxial growth may activate the doping.

When a DFB laser is being fabricated, a distributed feedback grating 150 is patterned on the lower epitaxial layer structure 144 prior to the step of overgrowing the upper epitaxial layer structure 146.

606: overgrowing an upper epitaxial layer structure 146 on the lower epitaxial layer structure 144 comprising the introduced material. In this example the upper epitaxial layer structure 146 is grown by MOCVD.

Thus, the patterning of the current blocking region 252, 256 in step 304, is by selective introduction of material 360 from above the active layer 125 into the lower epitaxial layer structure 144 and the upper epitaxial layer structure 146 is overgrown above the active layer 125 on the lower epitaxial layer structure 144.

608: There is no etched ridge waveguide, so the step of etching a ridge described with reference to FIG. 3 is skipped.

The remaining fabrication steps may be similar to those described with reference to FIGS. 1 and 2. An insulating dielectric material is not needed for this embodiment. The dielectric is useful on a ridge waveguide as an electrical insulator under the metal and as a part of the ridge waveguide's refractive index profile. However, it acts as a thermal barrier reducing heat dissipation, so if it is not required with the ridge, it can be omitted.

On the other hand, a dielectric under the metallisation can help with metal and bond adhesion, so in an alternative example (not shown), an insulating dielectric material 118 covers most of the top surface, and a contact window is opened up in the dielectric above and overlapping the channel 254. Subsequently, metal 116 is deposited making contact through the contact window to the contact semiconductor layer 120 above and overlapping the channel.

A pad of the metal 116 at one side of the channel is used as an area for soldering or bonding to the metal. In subsequent fabrication steps, a patterned hard mask and facet etch defines front and rear etched facets at either end of the channel 254. The facet etch creates an etched surface, which extends either side of the etched facet.

After the facet etch, an anti-reflective (AR) coating is applied to one etched facet and a high-reflectance (HR) coating (or an AR coating) is applied to the other etched facet at the other end of the channel 254. Anti-reflective coatings may be applied to just one facet for a laser, or one or both facets for Semiconductor Optical Amplifiers (SOAs) or Electro-Absorption Modulators (EAMs).

Finally, a metallisation step coats the underside of the wafer with metal 142.

With reference to the last step 608 in FIG. 6, dotted arrows show the current flow. A large area low-resistance contact is made by the metal layer 116 to the contact semiconductor layer 120. The current flow is laterally confined to the channel 254 by the blocking implants 652, 654. Current cannot leak outside the channel because the shallow implants extend laterally outwards from the channel, in this example to the edge of the chip. Therefore just the centre of the optical mode is supplied with current.

In this embodiment with no ridge waveguide, lateral optical confinement is still present, despite the lack of a ridge structure in the refractive index profile. The refractive index profile in and around the channel is dependent on current and temperature, in a way that provides an optical waveguide with at least some optical confinement.

A flared channel such as shown in FIG. 5 may be defined using the process described with reference to FIG. 6, again with no ridge waveguide superimposed on the channel.

FIG. 7 illustrates, in schematic form, steps from a method of fabrication of a photonic device in accordance with another embodiment of the present invention, with cross-section views. The method has the steps:

702: growing a lower epitaxial layer structure 144 comprising an active layer structure 125. The lower epitaxial layer further comprises a current blocking layer 726 above the active layer and having a first conductivity type. In this example, it is an n-type layer, replacing the p-type InP spacer layer 126 described with reference to FIG. 3. Alternatively, rather than replacing the spacer layer, the current blocking layer may be added to the epitaxial layer stack. The current blocking layer 726 may be grown directly on the upper interface of the active layers 125, or may be separated, for example by an intervening layer or layers. When a DFB laser is being fabricated, the lower epitaxial layer structure 146 may further comprise a grating layer 124.

704: patterning a current blocking region 252, 256 by selective introduction of material 760 into the lower epitaxial layer structure 144 to define a channel 254.

The species of the implant or diffusion doping is selected to form the channel in the current blocking layer, with the channel having an opposite conductivity type to the first conductivity type. Thus the current blocking region is formed in an epitaxial current blocking layer with a first type of doping (e.g. a current blocking p-type layer between n-type layers) that is patterned by selective area doping implant or doping diffusion of a second, opposite conductivity type of doping (e.g. n-type) in the area of the channel, to compensate the first type of doping so as to open a channel in the current blocking layer. In other words the blocking function of the blocking layer is deactivated to form a channel in the selected areas where the dopant of the second type is introduced.

With reference to FIG. 7, the steps shown 702, 704 may be followed by other steps to fabricate a ridge waveguide, such as described with reference to FIG. 3, namely 306: overgrowing an upper epitaxial layer structure 146 on the lower epitaxial layer structure 144 that comprises the already patterned current blocking region, and 308: etching a ridge waveguide 204 into the upper epitaxial layer structure 146 superimposed on the channel 254.

Alternatively, with reference to FIG. 7, the steps shown 702, 704 may be followed by other steps such as described with reference to FIG. 6, namely 606: overgrowing an upper epitaxial layer structure 146 on the lower epitaxial layer structure 144 comprising the introduced material, and 608: where there is no etched ridge waveguide, so the step of etching a ridge described with reference to FIG. 3 is skipped.

A pad of the metal 116 at one side of the channel is used as an area for soldering or bonding to the metal. In subsequent fabrication steps, a patterned hard mask and facet etch defines front and rear etched facets at either end of the channel 254. The facet etch creates an etched surface, which extends either side of the etched facet.

After the facet etch, an anti-reflective (AR) coating is applied to one etched facet and a high-reflectance (HR) coating (or an AR coating) is applied to the other etched facet at the other end of the channel 254. Anti-reflective coatings may be applied to just one facet for a laser, or one or both facets for Semiconductor Optical Amplifiers (SOAs) or Electro-Absorption Modulators (EAMs).

Finally, a metallisation step coats the underside of the wafer with metal 142.

In all the examples described with reference to FIGS. 2 to 7, an array of channels (with or without ridges) may be defined on one chip, for example to make a monolithic array of photonic devices such as DFB lasers.

Embodiments provide several advantages. The separately patterned implant step of embodiments with ridges makes the lateral current confinement independent of the ridge width. The lateral current confinement being decoupled from the waveguide width allows design flexibility and injection into the preferred transverse optical mode. The process is compatible with the standard MOCVD overgrowth step used for buried gratings in DFB ridge lasers.

Further advantages of embodiments with or without ridges are that current spreading is reduced by having implants close to the active layers and the shallow implants have low damage and less lateral process variation than other lateral confinement techniques. Furthermore, use of a implant by embodiments does not require special etches or layers.

1. A photonic device comprising:
a lower epitaxial layer structure comprising:
an active layer structure; and
a channel defined by a current blocking region patterned by selective introduction of material into the lower epitaxial layer structure; and
an upper epitaxial layer structure overgrown on the lower epitaxial layer structure comprising the introduced material.

2. The photonic device of claim 1, wherein the lower epitaxial layer structure comprises a grating layer and the photonic device further comprises a distributed feedback grating patterned into the grating layer.

3. The photonic device of claim 1, wherein the upper epitaxial layer structure comprises a cladding layer under a contact layer.

4. The photonic device of claim 1, further comprising a ridge waveguide etched into the upper epitaxial layer structure and superimposed on the channel.

5. The photonic device of claim 4, wherein a ratio of width of the channel to width of the ridge waveguide varies along the length of the channel.

6. The photonic device of claim 5, wherein the channel has a constant width along the length of the channel.

7. The photonic device of claim 5, wherein the ridge waveguide has a constant width along the length of the channel.

8. The photonic device of claim 4, wherein the ridge waveguide is wider than the channel, along the whole length of the channel.

9. The photonic device of claim 1, wherein the selective introduction of material is selected from the group consisting of: ion implantation, selective area isolation implantation, selective area doping implantation and selective area doping diffusion.

10.-13. (canceled)

14. The photonic device of claim 1, wherein the photonic device is a laser.

15. A photonic chip comprising the photonic device of claim 1.

16. A photonic chip assembly comprising:
the photonic chip of claim 15; and
a photonic integrated circuit having a receiving waveguide aligned to receive a beam of radiation from the photonic chip, the beam having propagated along the channel.

17. A photonic chip assembly comprising:
the photonic chip of claim 15; and
a photonic integrated circuit having a launching waveguide aligned to launch a beam of radiation to the photonic chip, the beam of radiation entering the channel to propagate along the channel.

18. A method of fabrication of a photonic device, the method comprising:
growing a lower epitaxial layer structure comprising an active layer structure;
patterning a current blocking region, by selective introduction of material into the lower epitaxial layer structure, to define a channel; and
overgrowing an upper epitaxial layer structure on the lower epitaxial layer structure comprising the introduced material.

19. The method of claim 18, further comprising etching a ridge waveguide into the upper epitaxial layer structure, superimposed on the channel.

20. The method of claim 19, further comprising patterning the ridge waveguide such that the ridge waveguide is wider than the channel, along the whole length of the channel.

21. The method of claim 18, wherein the lower epitaxial layer structure comprises a grating layer and the method further patterning a distributed feedback grating on the grating layer prior to the overgrowing the upper epitaxial layer structure.

22. The method of claim 18, wherein the upper epitaxial layer structure comprises a cladding layer under a contact layer.

23. The method of claim 18, wherein the patterning the current blocking region comprises selective introduction of material is selected from the group consisting of: ion implantation, selective area isolation implantation, selective area doping implantation and selective area doping diffusion.

24.-27. (canceled)
